(19) United States
(12) Patent Application Publication
(10) Pub. No.: US 2005/0036374 A1
(43) Pub. Date: Feb. 17, 2005

(54) Probe card substrate

(76) Inventors: Masanari Nakashima, Hyogo (JP); Shigekasu Tanaka, Hyogo (JP)

Correspondence Address: BAKER & DANIELS;111 E. WAYNE STREET, SUITE 800, FORT WAYNE, IN, 46802, US

(21) Appl. No.: 10/914,519

(22) Filed: Aug. 9, 2004

(30) Foreign Application Priority Data
Aug. 12, 2003 (JP) 2003-207391

(51) Int. Cl. G11C 11/34

(52) U.S. Cl. 365/202

(57) ABSTRACT

It is an object of the present invention to provide a probe card substrate for measuring electrical characteristics of a semiconductor device such as an LSI chip. A probe card substrate comprises a main substrate connected to a measuring device for testing a semiconductor device, a sub substrate on which a contact connected to the semiconductor device is mounted, and a conductive component electrically connecting both, in which the main substrate and the sub substrate are connected to be fixed and electrodes provided on a surface of the main substrate opposed to the sub substrate and electrodes provided on a surface of the sub substrate opposed to the main substrate are electrically connected.

### BACKGROUND OF THE INVENTION

1. Field of the Invention

The present invention relates to a probe card substrate for measuring electrical characteristics of a semiconductor device such as an LSI chip.

2. Description of the Background Art

As shown in FIG. 4, conventionally, a probe card substrate comprises a main substrate 1′ comprising a first main surface 1a′ having first connection electrodes 3′ connected to a measuring device for testing a semiconductor device and a second main surface 1b′ having second connection electrodes 4′ electrically connected to the first connection electrodes through wirings; a sub substrate 2′ comprising a second main surface 2b′ having fourth connection electrodes 6′ connected to contacts which come in contact with a tested object (semiconductor device) and a first main surface 2a′ having third connection electrodes 5′ electrically connected to fourth connection electrodes 4′ through wirings; and dogleg-shaped connection pins 9′ connecting one end thereof from a middle substrate 7′ provided between the main substrate 1′ and the sub substrate 2′ to the second connection electrodes 4′ of the main substrate 1′, and connecting the other end thereof to the third connection electrodes 5′ of the sub substrate 2′.

However, according to this kind of probe card substrate, when the connection pin 9′ connects one end to the second connection electrodes 4′ of the main substrate 1′ and connects the other end to the third connection electrodes 5′ of the sub substrate 2′, there are at least two points of electrical contacts such as a point between the second main surface of the main substrate 1′ and one end of the connection pin 9′ and a point between the first main surface of the sub substrate 2′ and the other end of the connection pin 9′ in the structure of the connection pin 9′ serving as a conductive component which connects the opposed electrodes, and the support substrate 7′ holding the connection pin 9′. In this constitution, it is difficult for the points to appropriately come in contact with each other, so that stability of electrical contact is lowered and contact resistance is generated. As a result, there is a problems that a conduction defect is liable to occur as the whole. In addition, since the bent connection pins 9′ are held by the support substrate 7′ in a state their lengths are increased, their directions, inclinations and the like are not uniform, the end positions of the connection pins 9′ are inaccurate and many conduction defects are generated.

For example, when the interval between the main substrate 1′ and the sub substrate 2′ is too long, sufficient contact pressure is not provided between both ends of the dogleg-shaped and thin connection pin 9′ and respective second connection electrode 4′ of the main substrate 1′ and the third connection electrode 5′ of the sub substrate 2′, so that contact resistance is generated. As a result, their contacts become unstable, causing the conduction defect.

Meanwhile, the interval between the main substrate 1′ and the sub substrate 2′ is too short, both ends of the dogleg-shaped and thin connection pin 9′ are largely bent and its end positions become unstable and could come off a range of contact with the second connection electrode 4′ of the main substrate 1′ or a range of contact with the third connection electrode 5′ of the sub substrate 2′. Consequently, satisfactory contact cannot be provided in this case also, causing the conduction defect.

Furthermore, path resistance always exists because of thin line of the connection pin 9′, which causes the conduction defect regardless of the interval between the main substrate 1′ and the sub substrate 2′. In addition, because of the thin line, the contact defect is liable to occur by the vibration or the shock.

### SUMMARY OF THE INVENTION

The present invention was made to solve the problems of the conventional probe card substrate, and it is an object of the present invention to provide a probe card substrate in which a contact defect between a main substrate and a sub substrate is prevented from occurring, stability of the electrical contact is high and high reliability is provided.

In order to solve the above problems, a probe card substrate according to the present invention comprises a main substrate connected to a measuring device for testing a semiconductor device, a sub substrate on which a contact connected to the semiconductor device is mounted, and a conductive component electrically connecting both, in which the main substrate and the sub substrate are connected to be fixed and electrodes provided on a surface of the main substrate opposed to the sub substrate and electrodes provided on a surface of the sub substrate opposed to the main substrate are electrically connected.

Besides, in order to solve the above problems, a probe card substrate according to the present invention comprises a main substrate connected to a measuring device for testing a semiconductor device, a sub substrate on which a contact connected to the semiconductor device is mounted, and a conductive component electrically connecting both, in which electrodes provided on a surface of the main substrate opposed to the sub substrate and electrodes provided on a surface of the sub substrate opposed to the main substrate are electrically connected by a conductive material.

In addition, in order to solve the above problems, a probe card substrate according to the present invention comprises a main substrate connected to a measuring device for testing a semiconductor device, a sub substrate on which a contact connected to the semiconductor device is mounted, and a conductive component electrically connecting both, in which the main substrate and the sub substrate are connected to be fixed by an electrically insulating adhesive agent.

Still further, in order to solve the above problems, according to the probe card substrate of the present invention, the main substrate is in the shape of a circle or an ellipse and the sub substrate is in the shape of a circle, an ellipse or a square.

Still further, in order to solve the above problems, according to the probe card substrate of the present invention, a plurality of socket holes are provided on the side not opposed to the main substrate, of the sub substrate, and socket terminals of a tested object can be inserted into the socket holes of the sub substrate.

### BRIEF DESCRIPTION OF THE DRAWINGS

FIG. 1 is a schematic view showing a sectional structure according to an embodiment of the present invention;

FIG. 2 is a schematic view showing a sectional structure according to another embodiment of the present invention;

FIG. 3 is an explanatory view showing another embodiment of a substrate of the present invention; and

FIG. 4 is a schematic view showing a sectional structure of a conventional probe card substrate.

### DESCRIPTION OF THE PREFERRED EMBODIMENTS

Hereinafter, an embodiment of the present invention is described with reference to the drawings.

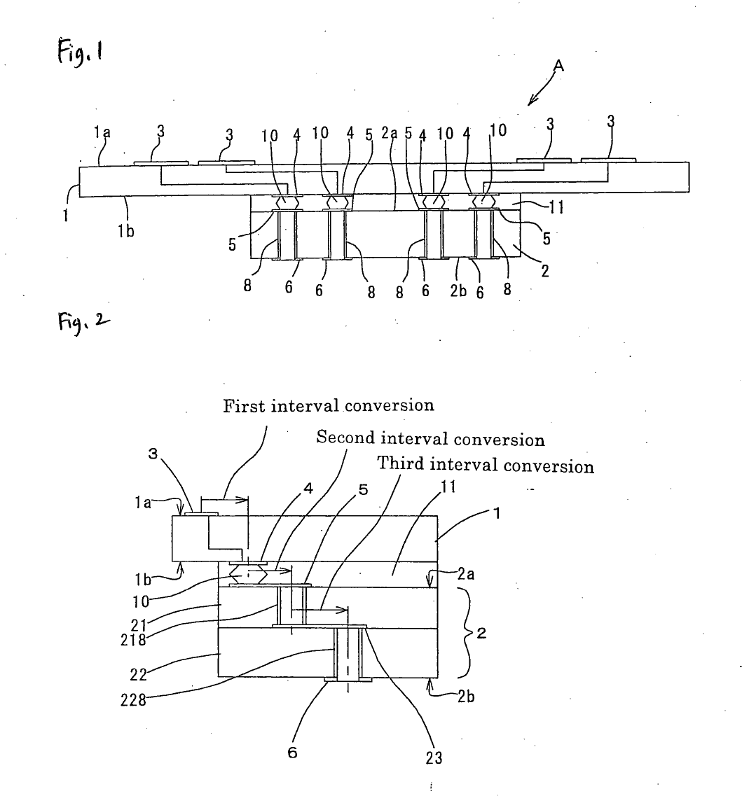

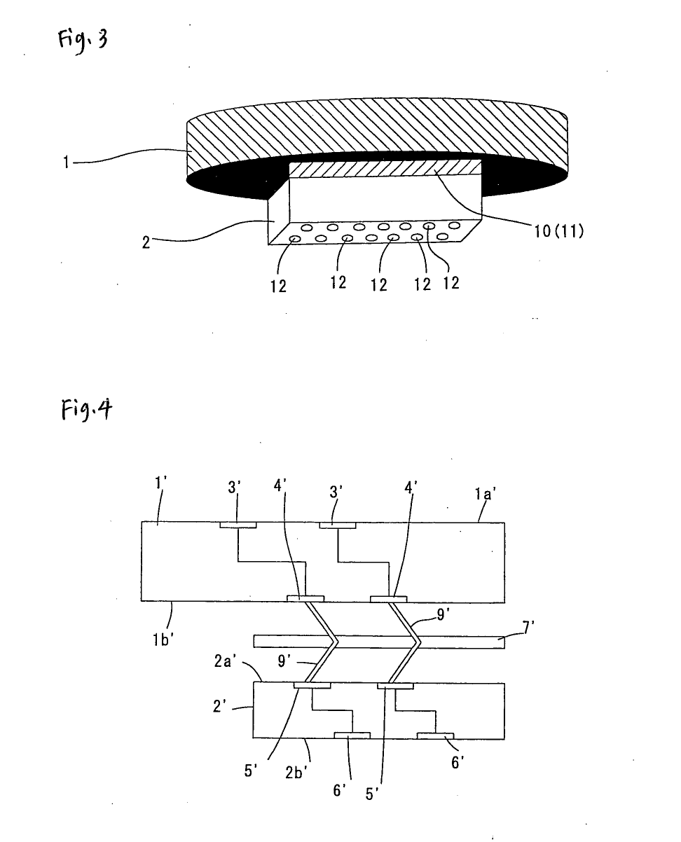

FIG. 1 is a schematic view showing a sectional structure according to the embodiment of the present invention, FIG. 2 is a schematic view showing a sectional structure according to another embodiment of the present invention, FIG. 3 is an explanatory view showing another embodiment of a substrate according to the present invention, and FIG. 4 is a schematic view showing a sectional structure of a conventional probe card substrate.

As shown in FIG. 1, a probe card A comprises a main substrate 1 having a plurality of first connection electrodes 3 which are electrically connected to a measuring device for testing a semiconductor device (not shown) such as a tester, and a sub substrate 2 having a plurality of fourth connection electrode 6 which are electrically connected to a tested object (semiconductor device, not shown). The main substrate 1 and sub substrate 2 are electrically connected through conductive materials 10 serving as conductive components.

As shown in FIG. 1, the main substrate 1 comprises the plurality of first connection electrodes 3 electrically connected to the electrodes of the measuring device (not shown) on a first main surface 1a, and a plurality of second connection electrodes 4 electrically connected to the sub substrate 2 as will be described below, on a second main surface 1b. The first connection electrodes 3 and the second connection electrodes 4 are electrically connected through wirings in the main substrate 1.

On the main substrate 1, first connection electrodes 3 are arranged such that an electrode interval is converted from a narrow interval between adjacent second connection electrodes 4 on the second main surface 1b to a wide interval between adjacent first connection electrodes 3 on the first main surface 1a to connect electrically to the electrodes of the measuring device (not shown).

The main substrate 1 is in the shape of a circle or an ellipse, whereby a distance of each wiring path of the plurality of first connection electrodes 3 on the first main surface 1a can be kept constant to prevent variation in resistance. Although this main substrate 1 is in the shape of the circle or the ellipse in this embodiment, the shape may be close to the circle or the ellipse. For example, it may be in the shape of a polygon such as an octagon.

As shown in FIG. 1, the sub substrate 2 comprises a plurality of third connection electrodes 5 on a first main surface 2aopposed to the second main surface 1b of the main substrate 1 and the plurality of fourth connection electrodes 6 electrically connected to the tested object (not shown), on a second main surface 2b. The third connection electrodes 5 and the fourth connection electrodes 6 are electrically connected via through holes 8 comprising electrically conductive plating layers.

The sub substrate 2 comprises the plurality of through holes 8 formed of electrically conductive plating layers which penetrate the sub substrate 2. An upper end of the through hole 8 is electrically connected to the third connection electrode 5 of the sub substrate 2 and a lower end thereof is electrically connected to the fourth connection electrode 6 of the sub substrate 2.

As shown in FIG. 2, the sub substrate 2 may comprise a first sub substrate 21 and a second sub substrate 22 in which a through hole 218 for the first sub substrate and a through hole 228 for the second sub substrate are arranged so as to be shifted with each other and the through hole 218 and the through hole 228 may be electrically connected via a sixth connection electrode 23.

Thus, since the sub substrate 2 comprises two layers and the positions of the two through holes 218 and 228 in the sub substrate 2 are shifted, when the electrode interval is converted from the interval between the first connection electrodes 3 of the main substrate 1 to the interval between the forth connection electrodes 6 of the sub substrate 2, the electrode interval is converted two times in the sub substrate 2. As a result, in this case, concentration of the wirings in the main substrate 1 can be dispersed to the sub substrate 2 as compared with the case the electrode interval is directly converted from the main substrate 1 by one through hole, so that wiring load in the main substrate 1 can be reduced. In addition, although the sub substrate 2 comprises the first sub substrate 21 and the second sub substrate 22 in FIG. 2, it may comprise three layers or more.

Although the sub substrate 2 is also in the shape of a circle or an ellipse, it may be in the shape of a rectangle along the configuration of the tested object (not shown) as shown in FIG. 3. Alternatively, it may be in the shape of a cubic, a triangle, a pentagon, a square or the like as long as it follows the configuration of the tested object (not shown).

The sub substrate 2 may be formed by a build-up method in which insulating layers are laminated on an insulating substrate to form a conductor pattern and conductor layers are build up to be multilayer through interlayer connection.

As shown in FIG. 1, the second connection electrodes 4 on the second main surface 1b of the main substrate 1 and the third connection electrodes 5 on the first main surface 2a of the sub substrate 2 are electrically connected by conductive materials 10 comprising a solder or a conductive resin. By using the conductive materials 10, contact resistance and path resistance can be reduced to a negligible level, so that stability of electrical contact between the main substrate 1 and the sub substrate 2 is considerably enhanced.

Besides the conductive materials 10 as the conductive component, an adhesive agent 11 of an insulating resin member is provided between the second main surface 1b of the main substrate 1 and the first main surface 2a of the sub substrate 2, to insulate a part other than the electrodes while electrically and stably connect the main substrate 1 and the sub substrate 2.

Since the second main surface 1b of the main substrate 1 and the first main surface 2a of the sub substrate 2 are stably connected by the adhesive agent 11 applied between them, the positional relationship between the main substrate 1 and the sub substrate 2 is kept stable and stability of electrical contact between the second connection electrodes 4 of the main substrate 1 and the third connection electrodes 5 of the sub substrate 2 can be enhanced by the conductive materials 10. As a result, mechanical strength as a probe card which integrates both of them is improved and durability on the occasion of repetitive use can be considerably improved.

FIG. 3 shows another embodiment of the substrate, in which a rectangular sub substrate 2 is arranged on a second main surface 1b of the circular main substrate 1, electrodes (not shown) are wired between the main substrate 1 and the sub substrate 2, a plurality of socket holes 12 are provided in the sub substrate 2, the main substrate 1 and the sub substrate 2 are electrically connected by a conductive material 10, the main substrate 1 and sub substrate 2 are connected by an adhesive agent 11 comprising an insulating resin material applied between them besides the conductive material 10, and socket terminals (not shown) of a tested object (not shown) can be inserted into the socket holes 12 of the sub substrate 2, so that it can be applied to tested objects having different shapes.

Although the above embodiments are described as representative examples of the present invention, the present invention is not limited to the above embodiments, and various modifications can be implemented within a scope which fulfills the required condition according to the present invention, attains the object of the present invention and provides the following effects.

As can be clear from the above description, the probe card substrate of the present invention comprises the main substrate connected to the measuring device for testing the semiconductor device, the sub substrate on which the contact connected to the semiconductor device is mounted, and the conductive component electrically connecting both, in which since it is constituted such that the main substrate and the sub substrate are connected to be fixed and the electrodes provided on the surface of the main substrate opposed to the sub substrate and the electrodes provided on the surface of the sub substrate opposed to the main substrate are electrically connected, there can be expected excellent effects that stability of the electrical contact is high, bad electrical contact between the main substrate and the sub substrate is prevented and high reliability is attained.

In addition, the probe card substrate of the present invention comprises the main substrate connected to the measuring device for testing the semiconductor device, the sub substrate on which the contact connected to the semiconductor device is mounted, and the conductive component electrically connecting both, in which since it is constituted such that the electrodes provided on the surface of the main substrate opposed to the sub substrate and the electrodes provided on the surface of the sub substrate opposed to the main substrate are electrically connected by the conductive material, contact resistance and path resistance can be reduced to a negligible level, stability of the electrical contact can be considerably enhanced, bad conduction between the substrates can be prevented and high reliability can be obtained.

In addition, the probe card substrate of the present invention comprises the main substrate connected to the measuring device for testing the semiconductor device, the sub substrate on which the contact connected to the semiconductor device is mounted, and the conductive component electrically connecting both, in which since it is constituted such that the main substrate and the sub substrate are connected to be fixed by the electrically insulating adhesive agent, a positional relation between the main substrate and the sub substrate is kept stable, stability of electrical contact between the main substrate and the sub substrate can be enhanced by the conductive material and high reliability can be provided. Furthermore, mechanical strength as the probe card which integrates both is improved and durability on the occasion of repetitive use can be considerably enhanced.

Besides, according to the probe card substrate of the present invention, since the sub substrate is in the shape of a circle, an ellipse or a square so as to adjust the configuration of the tested object and the main substrate is in the shape of a circle or an ellipse so as to equalize wiring lengths to the measuring device, a distance of the wiring path can be held constant, variation in resistance can be prevented and more accurate testing operation can be performed.

Besides, according to the probe card substrate of the present invention, since it is constituted such that the plurality of socket holes are provided in the sub substrate and socket terminals of the tested object can be inserted into the socket holes, it can be applied to tested objects having different shapes.

1. A probe card substrate comprising:
a main substrate connected to a measuring device for testing a semiconductor device;
a substrate on which a contact connected to the semiconductor device is mounted; and
a conductive component electrically connecting both,
wherein the main substrate and the sub substrate are connected to be fixed and electrodes provided on a surface of the main substrate opposed to the sub substrate and electrodes provided on a surface of the sub substrate opposed to the main substrate are electrically connected.

2. The probe card substrate according to claim 1, comprising:
a main substrate connected to a measuring device for testing a semiconductor device;
a sub substrate on which a contact connected to the semiconductor device is mounted; and
a conductive component electrically connecting both,
wherein electrodes provided on a surface of the main substrate opposed to the sub substrate and electrodes provided on a surface of the sub substrate opposed to the main substrate are electrically connected by a conductive material.

3. The probe card substrate according to claim 1, comprising:
main substrate connected to a measuring device for testing a semiconductor device;
a sub substrate on which a contact connected to the semiconductor device is mounted; and
a conductive component electrically connecting both,
wherein the main substrate and the sub substrate are connected to be fixed by an electrically insulating adhesive agent.

4. The probe card substrate according to claim 1, wherein the main substrate is in the shape of a circle or an ellipse and the sub substrate is in the shape of a circle, an ellipse or a square.

5. The probe card substrate according to claim 1, wherein a plurality of socket holes are provided on the side no opposed to the main substrate, of the sub substrate, and socket terminals of a tested object can be inserted into the socket holes of the sub substrate.

6. The probe card substrate according to claim 2, comprising:
main substrate connected to a measuring device for testing a semiconductor device;
a sub substrate on which a contact connected to the semiconductor device is mounted; and
a conductive component electrically connecting both,
wherein the main substrate and the sub substrate are connected to be fixed by an electrically insulating adhesive agent.

7. The probe card substrate according to claim 2, wherein the main substrate is in the shape of a circle or an ellipse and the sub substrate is in the shape of a circle, an ellipse or a square.

8. The probe card substrate according to claim 3, wherein the main substrate is in the shape of a circle or an ellipse and the sub substrate is in the shape of a circle, an ellipse or a square.

9. The probe card substrate according to claim 2, wherein a plurality of socket holes are provided on the side no opposed to the main substrate, of the sub substrate, and socket terminals of a tested object can be inserted into the socket holes of the sub substrate.

10. The probe card substrate according to claim 3, wherein a plurality of socket holes are provided on the side no opposed to the main substrate, of the sub substrate, and socket terminals of a tested object can be inserted into the socket holes of the sub substrate.

11. The probe card substrate according to claim 4, wherein a plurality of socket holes are provided on the side no opposed to the main substrate, of the sub substrate, and socket terminals of a tested object can be inserted into the socket holes of the sub substrate.
